(19) United States
(12) Patent Application Publication
(10) Pub. No.: US 2025/0056930 A1
(43) Pub. Date: Feb. 13, 2025

(54) SEMICONDUCTOR DEVICE

(71) Applicant: EPISTAR CORPORATION, Hsinchu (TW)

(72) Inventors: Tzu Yun Feng, Hsinchu (TW); Wei Shan Yeoh, Hsinchu (TW); Yao-Ning Chan, Hsinchu (TW); June Kuo, Hsinchu (TW)

(21) Appl. No.: 18/799,505

(22) Filed: Aug. 9, 2024

(30) Foreign Application Priority Data
Aug. 11, 2023 (TW) 112130342

(51) Int. Cl. H01L 33/38; H01L 33/22; H01L 33/40; H01L 33/44; H01L 33/50; H01L 33/52; H01L 33/62; H01L 33/64

(52) U.S. Cl. CPC H01L 33/387; H01L 33/22; H01L 33/405; H01L 33/44; H01L 33/50; H01L 33/52; H01L 33/62; H01L 33/647

(57) ABSTRACT

A semiconductor device includes a semiconductor stack, an insulating structure, a metal oxide structure and a metal structure. The semiconductor stack includes a first semiconductor structure, a second semiconductor structure and an active structure located between the first semiconductor structure and the second semiconductor structure. The insulating structure is disposed below the first semiconductor structure and comprising a first opening and a second opening. The metal oxide structure is disposed below the insulating structure and located in the first opening, and contacts the semiconductor stack to form a first contact surface therebetween. The metal structure is located in the second opening, and contacts the semiconductor stack to form a second contact surface therebetween. The first contact surface is separated from the second contact surface.

### TECHNICAL FIELD

The present disclosure relates to a semiconductor light-detecting device, and particularly to a semiconductor light-detecting device including a first absorption layer, a second absorption layer and a first semiconductor layer.

### CROSS REFERENCE TO RELATED APPLICATION

This application claims the right of priority based on TW application Serial No. 112130342, filed on Aug. 11, 2023, and the content of which is hereby incorporated by reference in its entirety.

### DESCRIPTION OF BACKGROUND ART

Semiconductor devices can be applied to a wide range of applications. Research and development of related materials have been continuously carried out. For example, a group III-V semiconductor material including a group III element and a group V element may be applied to various optoelectronic semiconductor devices, such as light-emitting diodes (LEDs), laser diodes (LDs), photodetectors (PDs), solar cells or power devices (such as switches or rectifiers). These optoelectronic semiconductor devices can be applied in various fields, such as illumination, medical care, display, communication, sensing, or power supply system.

As one of the major applications, LEDs are widely used in fields of display, lighting and communication because of advantages of low energy consumption, rapid response, small volume and long operating lifetime, and lower power consumption, smaller chip size and better photoelectric conversion efficiency have always been the focus of industry research and development.

### SUMMARY OF THE DISCLOSURE

The present disclosure provides a semiconductor device, which includes a semiconductor stack, an insulating structure, a metal oxide structure and a metal structure. The semiconductor stack includes a first semiconductor structure, a second semiconductor structure and an active structure located between the first semiconductor structure and the second semiconductor structure. The insulating structure is disposed below the first semiconductor structure and comprising a first opening and a second opening. The metal oxide structure is disposed below the insulating structure and located in the first opening, and contacts the semiconductor stack to form a first contact surface therebetween. The metal structure is located in the second opening, and connects contacts the semiconductor stack to form a second contact surface therebetween. The first contact surface is separated from the second contact surface.

### BRIEF DESCRIPTION OF THE DRAWINGS

The foregoing aspects and many of the attendant advantages of the present disclosure will become more readily appreciated as the same becomes better understood by reference to the following detailed description, when taken in conjunction with the accompanying drawings, wherein:

FIG. 1 shows a perspective top view of a semiconductor device according to one embodiment of the present disclosure;

FIG. 2 shows a schematic sectional view of the semiconductor device along a section line A-A′ in FIG. 1A;

FIG. 3A shows a partial enlarged view of region B of the semiconductor device in FIG. 1;

FIGS. 3B and 3C shows partial enlarged views of semiconductor devices according to other embodiments of the present disclosure;

FIG. 4 shows a schematic sectional view of a semiconductor device according to one embodiment of the present disclosure;

FIG. 5 shows a schematic sectional view of a package structure according to one embodiment of the present disclosure.

### DETAILED DESCRIPTION OF PREFERRED EMBODIMENTS

The following embodiments will be described with accompany drawings to disclose the concept of the present disclosure. In the drawings or description, same or similar portions are indicated with same or similar numerals. Furthermore, a shape or a size of a member in the drawings may be enlarged or reduced. Particularly, it should be noted that a member which is not illustrated or described in drawings or description may be in a form that is known by a person skilled in the art.

A person skilled in the art can realize that addition of other components based on a structure recited in the following embodiments is allowable. For example, if not otherwise specified, a description similar to “a first layer/structure is on or under a second layer/structure” may include an embodiment in which the first layer/structure directly (or physically) contacts the second layer/structure, and may also include an embodiment in which another structure is provided between the first layer/structure and the second layer/structure, such that the first layer/structure and the second layer/structure do not physically contact each other. In addition, it should be realized that a positional relationship of a layer/structure may be altered when being observed in different orientations.

In addition, if not otherwise specified, a description similar to “a first layer/structure is on or under a second layer/structure” may include an embodiment in which the first layer/structure directly (or physically) contacts the second layer/structure, and may also include an embodiment in which another structure is provided between the first layer/structure and the second layer/structure, such that the first layer/structure and the second layer/structure do not directly contact each other. Furthermore, it should be realized that a positional relationship of a layer/structure may be altered when being observed in different orientations.

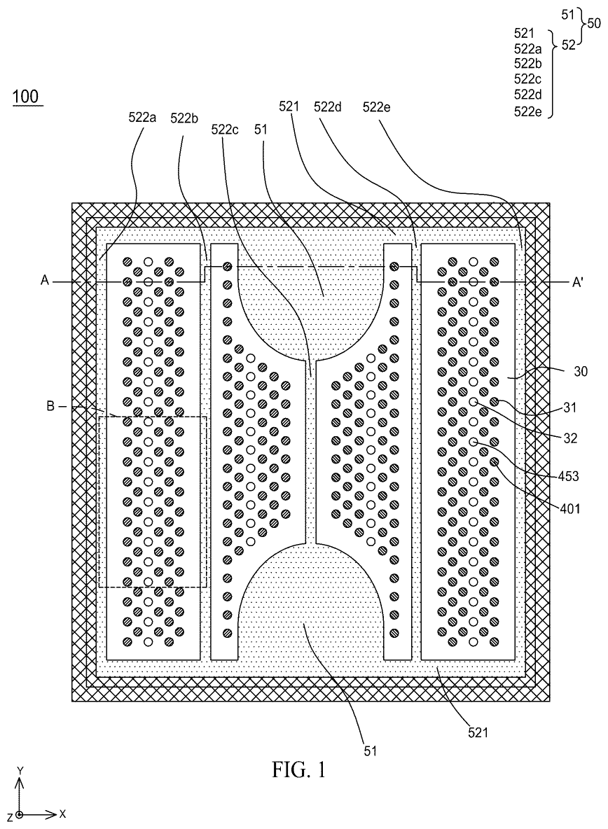

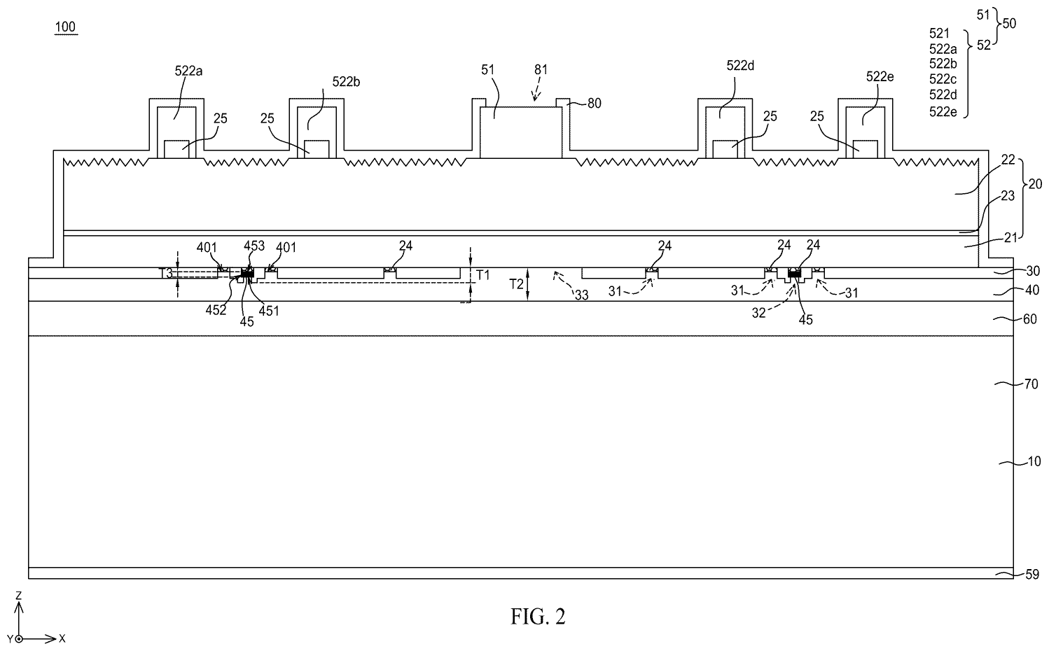

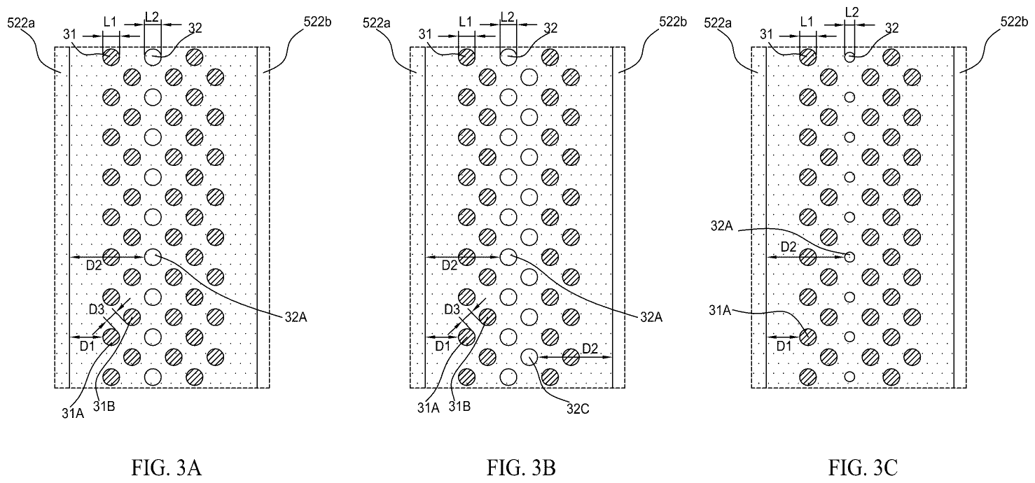

FIG. 1 is a perspective top view of a semiconductor device 100 according to one embodiment of the present disclosure. FIG. 2 is a schematic sectional view of the semiconductor device 100 in FIG. 1 along section line A-A′. FIG. 3A is a partial enlarged view of region B of the semiconductor device 100 in FIG. 1.

As shown in FIG. 2, the semiconductor device 100 includes a semiconductor stack 20, an insulating structure 30 located at one side of the semiconductor stack 20, a first conductive structure 40 located on one side of the insulating structure 30 away from the semiconductor stack 20, and a second conductive structure 45 located between the semiconductor stack 20 and the first conductive structure 40. Further, the semiconductor device 100 may optionally include a base 10 located at one side of the first conductive structure 40 away from the semiconductor stack 20, a first electrode structure 50 located on the semiconductor stack 20, and/or a second electrode structure 59 located below the first conductive structure 40 or the base 10. The base 10 provides the mechanical strength for supporting the semiconductor device 100. In this embodiment, the base 10 is a permanent substrate that supports the semiconductor stack 20. In other embodiments, the base 10 may be a growth substrate for the semiconductor stack 20 to grow thereon.

The semiconductor stack 20 includes a first semiconductor structure 21, a second semiconductor structure 22 and an active structure 23 located between the first semiconductor structure 21 and the second semiconductor structure 22. The first semiconductor structure 21 is closer to the base 10 than the second semiconductor structure 22. The first semiconductor structure 21 and the second semiconductor structure 22 have different conductive types. For example, the first semiconductor structure 21 is p-type semiconductor and the second semiconductor structure 22 is n-type semiconductor; or the first semiconductor structure 21 is n-type semiconductor and the second semiconductor structure 22 is p-type semiconductor. In this embodiment, the semiconductor device 100 is a light-emitting device, and the first semiconductor structure 21 and the second semiconductor structure 22 can respectively provide holes and electrons (or electrons and holes) to the active structure 23, and the holes and electrons can recombine in the active structure 23 to emit a light with a specific wavelength. The p-type semiconductor may be a semiconductor doped with carbon (C), zinc (Zn), beryllium (Be) or magnesium (Mg). The n-type semiconductor may be a semiconductor doped with silicon (Si), germanium (Ge), tin (Sn), selenium (Se) or tellurium (Te). In one embodiment, the first semiconductor structure 21 and/or the second semiconductor structure 22 may have a doping concentration between 5×10¹⁶/cm³ and 1×10²⁰/cm³.

In one embodiment, the first semiconductor structure 21 and/or the second semiconductor structure 22 may include a single layer or multiple layers, and may include a confinement layer and/or a cladding layer. The semiconductor stack 20 may include a single heterostructure, a double heterostructure (DH), a double-side double heterostructure (DDH) or a multiple quantum well (MQW) structure.

During operation of the semiconductor device 100, the active structure 23 emits a light with a peak wavelength. The light includes visible light and/or invisible light. The peak wavelength of the light is determined by the material composition of the active structure 23. For example, when the material of the active structure 23 includes InGaN, it may emit a blue light or a deep blue light with a peak wavelength of 400 nm to 490 nm, a green light with a peak wavelength of 490 nm to 550 nm or a red light with a peak wavelength of 560 nm to 650 nm; when the material of the active structure 23 includes AlGaN, it may emit an ultraviolet light with a peak wavelength of 250 nm to 400 nm; when the material of the active structure 23 includes InGaAs, InGaAsP, AlGaAs or AlGaInAs, it may emit an infrared light with a peak wavelength of 700 nm to 1700 nm; when the material of the active structure 23 includes InGaP or AlGaInP, it may emit a red light with a peak wavelength of 610 nm to 700 nm, or a yellow light with a peak wavelength of 530 nm to 600 nm. The semiconductor stack 20 includes a light-emitting surface, and the light generated by the active structure 23 is emitted outwards from the light-emitting surface. In this embodiment, the light-emitting surface is a surface of the second semiconductor structure 22 away from the active structure 23. The light-emitting surface can be optionally roughened to improve light extraction efficiency of the semiconductor device 100.

In some embodiments, the semiconductor stack 20 may optionally include a first contact structure 24. The first contact structure 24 is disposed between the first semiconductor structure 21 and the insulating structure 30. The first contact structure 24 can be patterned, and a portion of a lower surface of the first semiconductor structure 21 is not in contact with the first contact structure 24. The number of the first contact structure 24 can be plural. As shown in FIG. 2, in this embodiment, the semiconductor stack 20 includes a plurality of first contact structures 24, which are physically separated from each other.

The first contact structure 24 may include semiconductor materials. In one embodiment, the first contact structure 24 and the first semiconductor structure 21 have the same conductive type, and the first contact structure 24 has a doping concentration higher than that of the first semiconductor structure 21. For example, the doping concentration of the first contact structure 24 can be between 1×10¹⁸/cm³ to 1×10²⁰/cm³. The first contact structure 24 can include a single layer or multiple layers. When the first contact structure 24 includes multiple layers, each layer thereof can have the same or different materials. In one embodiment, the first contact structure 24 may have a thickness between 5 nm and 100 nm, such as 5 nm, 10 nm, 35 nm, 50 nm, 75 nm or 100 nm.

Referring to FIG. 2, the insulating structure 30 is located between the semiconductor stack 20 and the base 10. The insulating structure 30 can be patterned, and includes a first opening 31 and a second opening 32 which are separated from each other. The plurality of first contact structures 24 may be disposed in the first opening 31 and the second opening 32. In other words, the first contact structure 24 corresponds to the first opening 31 and the second opening 32. In some embodiments, the insulating structure 30 may have a plurality of first openings 31 and/or a plurality of second openings 32, and the plurality of first contact structures 24 can be correspondingly disposed in the plurality of first openings 31 and/or the plurality of second openings 32. As shown in FIG. 2, in this embodiment, the plurality of first contact structures 24 is disposed in the plurality of first openings 31 and the plurality of second openings 32 in a one-to-one manner, and the portion of the lower surface of the first semiconductor structure 21 which is not in contact with the plurality of first contact structures 24 directly contacts the insulating structure 30. In other words, the first contact structure 24 does not overlap with the insulating structure 30 in a vertical direction (along Z-axis). In one embodiment, the insulating structure 30 may have a refractive index smaller than that of the first contact structure 24 (or the first semiconductor structure 21), so as to increase reflection of the light emitted from the active structure 23 at an interface between and the insulating structure 30 and the first contact structure 24 (or between the insulating structure 30 and the first semiconductor structure 21). Thus, the light emitted by active structure 23 can be concentrated to emit outwards from the light-emitting surface.

The first conductive structure 40 is disposed between the insulating structure 30 and the base 10 and can enhance current spreading in a horizontal direction (along X-axis and/or Y-axis). The second conductive structure 45 is disposed between the semiconductor stack 20 and the first conductive structure 40. Specifically, the first conductive structure 40 is disposed below the insulating structure 30 and located in the first opening 31, and may extend into the second opening 32. The second conductive structure 45 is located in the second opening 32 and is not located in the first opening 31. The number of the second conductive structure 45 can be plural. As shown in FIG. 2, in this embodiment, there are a plurality of second conductive structures 45 which is correspondingly disposed in the plurality of second openings 32. In the top view, in each of the second openings 32, the second conductive structure 45 has a shape substantially the same as that of the second opening 32.

As shown in FIG. 2, in each of the first openings 31, the first conductive structure 40 contacts the first contact structure 24. In each of the second openings 32, the second conductive structure 45 contacts the first contact structure 24 and the first conductive structure 40. In one embodiment that the semiconductor stack 20 does not include the plurality of first contact structures 24 (not shown), the first conductive structure 40 contacts the first semiconductor structure 21 in each of the first openings 31, and the second conductive structure 45 contacts the first semiconductor structure 21 and the first conductive structure 40 in each of the second openings 32. In other words, the first conductive structure 40 can directly connect the first contact structure 24 (or the first semiconductor structure 21) through the first opening 31 and indirectly connect the first contact structure 24 (or the first semiconductor structure 21) through the second opening 32, so that current can flow in or out the first contact structure 24 (or the first semiconductor structure 21) through the first opening 31 and the second opening 32.

By adjusting quantity, size and/or distribution of the first openings 31 and the second openings 32 of the insulating structure 30, the current distribution of the semiconductor stack 20 can be controlled, so as to adjust the uniformity of light emission of the semiconductor device 100. The first contact structure 24 can lower the resistance between the first semiconductor structure 21 and the first conductive structure 40 and the resistance between the first semiconductor structure 21 the second conductive structure 45, so as to reduce an operating voltage of the semiconductor device 100. In some embodiments, the first contact structures 24 may be selectively disposed in the plurality of first openings 31 and/or the plurality of second openings 32. For example, the first contact structures 24 may not be disposed in the plurality of first openings 31, or may be disposed in a part of the plurality of the first openings 31 to precisely adjust uniformity of current distribution of the semiconductor stack 20.

Referring to the partial enlarged view of FIG. 3A. In the top view, the first opening 31 and the second opening 32 respectively have a first width L1 and a second width L2. The first width L1 may be larger than or equal to the second width L2. In one embodiment, the first width L1 can be between 6 μm and 15 μm, and the second width L2 can be between 4.5 μm and 10 μm. Referring to FIG. 2, the second opening 32 has an upper end close to the first semiconductor structure 21 and a lower end away from the first semiconductor structure 21. As shown in FIGS. 1 and 3A to 3C, when viewed from the top, only the upper end of each of the second openings 32 can be seen, and the second width L2 is the width of the upper end. The second conductive structure 45 located in the second opening 32 includes a first surface 451 facing the first conductive structure 40 and a side surface 452 which is not parallel to the first surface 451. In this embodiment, the insulating structure 30 conformally covers the side surface 452 and a part of the first surface 451 and forms a stepped structure protruding along the vertical direction (along Z-axis). Therefore, an area of the insulating structure 30 is increased to improve reliability of the semiconductor device 100 and increase reflection effect of the light emitted from the active structure 23. In this embodiment, the lower end of the second opening 32 has a width different from the second width L2 of the upper end. In one embodiment, the width of the lower end may be the same as the second width L2 of the upper end. In one embodiment, in the horizontal direction (along X-axis or Y-axis), the second conductive structure 45 has a width substantially equal to the second width L2 of the second opening 32.

Further, a contact surface between the semiconductor stack 20 and the first conductive structure 40 can be defined as a first contact surface 401, and a contact surface between the semiconductor stack 20 and the second conductive structure 45 can be defined as a second contact surface 453. Specifically, as shown in FIG. 2, the contact surface between the first contact structure 24 and the first conductive structure 40 located in the first opening 31 is the first contact surface 401, and the contact surface between the first contact structure 24 and the second conductive structure 45 located in the second opening 32 is the second contact surface 453. In the embodiment that the semiconductor stack 20 does not have the first contact structure 24 (not shown), the first conductive structure 40 directly contacts the first semiconductor structure 21 and forms the first contact surface 401 therebetween, and the second conductive structure 45 directly contacts the first semiconductor structure 21 and forms the second contact surface 453 therebetween. In the top view, the position of the first contact surface 401 corresponds to the position of the first opening 31, and the position of the second contact surface 453 corresponds to the position of the second opening 32. Furthermore, the first contact surface 401 and the first opening 31 can have the same quantity, and the second contact surface 453 and the second opening 32 can have the same quantity. In one embodiment, the second contact surface 453 has a resistance lower than that of the first contact surface 401.

In one embodiment, in the vertical direction (along Z-axis), the insulating structure 30 has a first thickness T1, the first conductive structure 40 has a second thickness T2, and the second conductive structure 45 has a third thickness T3. The first thickness T1 can be smaller than or equal to the second thickness T2. The first thickness T1 can be greater than or equal to the third thickness T3. In this embodiment, the first thickness T1 is smaller than the second thickness T2 and larger than the third thickness T3. In one embodiment, the first thickness T1 of the insulating structure 30 can be between 20 nm and 180 nm. The third thickness T3 of the second conductive structure 45 can be between 100 nm and 500 nm.

Referring to FIGS. 1 to 2, the first electrode structure 50 is disposed on the surface of the second semiconductor structure 22 away from the active structure 23, and is electrically connected to the second semiconductor structure 22. The second electrode structure 59 is disposed below the base 10 and is electrically connected to the first semiconductor structure 21, so that the semiconductor device 100 forms a vertical type light-emitting device. The first electrode structure 50 includes a pad 51 and an extending portion 52 connected to the pad 51, and the extending portion 52 may improve uniformity of current distribution in the second semiconductor structure 22. In this embodiment, the extending portion 52 includes a first section 521 extending from the pad 51, and a plurality of second sections 522a, 522b, 522c, 522d and 522e which are connected to the first section 521 and/or the pad 51 and are not parallel to the first section 521. In one embodiment, the plurality of second sections 522a, 522b, 522c, 522d and 522e are parallel to and separated from each other.

In some embodiments, the semiconductor stack 20 may optionally include a second contact structure 25. The second contact structure 25 is disposed between the second semiconductor structure 22 and the first electrode structure 50, so as to reduce the resistance between the second semiconductor structure 22 and the first electrode structure 50 and lower the operating voltage of the semiconductor device 100. The second contact structure 25 can be patterned, and the number of the second contact structure 25 can be plural. As shown in FIG. 2, in this embodiment, the semiconductor stack 20 includes a plurality of second contact structures 25 which are separated from each other. The plurality of second contact structures 25 can be disposed corresponding to all or a part of the extending portion 52 to facilitate current spreading. For example, the plurality of second contact structures 25 is disposed below the plurality of second sections 522a, 522b, 522c, 522d and 522e, and can be optionally disposed below the first section 521 (not shown). In one embodiment, in the horizontal direction (along X-axis), each of the second contact structures 25 may have a width smaller than or equal to that of each of the second sections 522a, 522b, 522c, 522d and 522c.

The second contact structure 25 may include semiconductor materials, and the second contact structure 25 and the second semiconductor structure 22 may have the same conductive type. The second contact structure 25 has a doping concentration higher than that of the second semiconductor structure 22. In one embodiment, the doping concentration of the second contact structure 25 can be between 1×10¹⁸/cm³ and 1×10²⁰/cm³. The second contact structure 25 can be a single layer or multiple layers (not shown). When the second contact structure 25 includes multiple layers, the material and/or doping concentration of each layer may be the same or different.

In some embodiments, the insulating structure 30 may not overlap with the pad 51 in the vertical direction for improving reliability. As shown in FIG. 2, the insulating structure 30 may optionally include a third opening 33 corresponding to the pad 51, and the third opening 33 has a width larger than that of the pad 51. The first conductive structure 40 extends into the third opening 33 and contacts the first semiconductor structure 21. Furthermore, the first contact structure 24 may optionally not be disposed below the pad 51 to avoid current concentration below the pad 51. The first contact structure 24 is not disposed in the third opening 33. Similarly, the second contact structure 25 may optionally not be disposed below the pad 51 to avoid current concentration below the pad 51. In other words, the insulating structure 30, the first contact structure 24 and/or the second contact structure 25 may not overlap with the pad 51 in the vertical direction.

Referring again to FIGS. 1 and 2, the first opening 31 and the second opening 32 do not overlap with the first electrode structure 50 in the vertical direction. As the current flows in or out the semiconductor stack 20 through the first opening 31 and the second opening 32, through the above arrangement of the first opening 31 and the second opening 32, light shield effect of the first electrode structure 50 can be reduced, and uniformity of current distribution can be improved. More specifically, the first opening 31 and the second opening 32 can be disposed between any two adjacent second sections 522a, 522b, 522c, 522d and 522e, such as between the second section 522a and the second section 522b, and/or between the second section 522b and the second section 522c, and/or between the second section 522c and the second section 522d, and/or between the second section 522d and the second section 522c.

Referring to FIG. 3A, in one embodiment, the plurality of second openings 32 is disposed in a central area between two adjacent second sections 522a and 522b. The plurality of first openings 31 is disposed between the plurality of second openings 32 and the two second sections 522a and 522b. Part or all of the plurality of first openings 31 are closer to the second section 522a or the second section 522b than the plurality of second openings 32. In this embodiment, each of the first openings 31 has a first distance D1 defined as the shortest distance from the edge thereof to the closest second section 522a or 522b. For example, for the first opening 31A in FIG. 3A, the second section 522a is the closest second section, and the shortest distance between the edge of the first opening 31A to the second section 522a is drawn as the first distance D1. Similarly, each of the second openings 32 has a second distance D2 defined as the shortest distance between the edge thereof to the closest second sections 522a or 522b. For example, for the second opening 32A in FIG. 3A, the shortest distance between the edge of the second opening 32A and the closest second section 522a is drawn as the second distance D2. The first distance D1 may be less than, equal to, or larger than the second distance D2. In one embodiment, the first distance D1 can be in a range of 5 μm to 50 μm, and the second distance D2 can be in a range of 20 μm to 100 μm.

Between the two adjacent second sections 522a and 522b, with respect to the plurality of second openings 32, the plurality of first openings 31 is closer to the second section 522a or the second section 522b to form shorter current path with lower resistance. When the semiconductor device 100 is in operation, the current distribution decreases from the second section 522a or the second section 522b to the central area between the second section 522a and the second section 522b. Therefore, light emission of the semiconductor device 100 is concentrated around the second section 522a and the second section 522b, and is easily blocked by the second section 522a and the second section 522b to lower the uniformity of light emission and the light extraction efficiency. In this embodiment, through disposing the second conductive structure 45 in the plurality of second openings 32, the second contact surface 453 with smaller resistance can be formed in the central area between the two adjacent second sections 522a and 522b to facilitate the current passing through the central area. As such, the operating voltage of the semiconductor device 100 can be reduced, and the uniformity of light emission and light extraction efficiency can be improved.

The plurality of first openings 31 and the plurality of second openings 32 can be arranged in an array to improve the uniformity of current distribution. As shown in FIG. 3A, in this embodiment, the plurality of second openings 32 is disposed in the central area between the second section 522a and the second section 522b, and can be arranged in a single column and parallel to the second section 522a and the second section 522b. The plurality of first openings 31 and the plurality of second openings 32 are arranged in an array, and the plurality of second openings 32 is arranged between the plurality of first openings 31. In this embodiment, the distance between each of the plurality of second opening 32 to the second section 522a is different from the distance between each of the plurality of second opening 32 to the second section 522b. In other embodiments, the distance between the each of plurality of second openings 32 to the second section 522a is equal to the distance between each of plurality of second openings 32 to the second section 522b (not shown). That is, the plurality of second openings 32 may be located in the center between the two adjacent second section 522a and 522b.

In the top view, the first opening 31 and/or the second opening 32 can be designed to have a shape of circle, polygon or irregular shapes, and the first opening 31 and the second opening 32 can be the same or different shapes. When the first opening 31 and/or the second opening 32 are circles, the first width L1 of the first opening 31 and/or the second width L2 of the second opening 32 are their diameters respectively. When the first opening 31 and/or the second opening 32 are polygons, the first width L1 and/or the second width L2 are their side lengths respectively. Further, In the top view, the first opening 31 has a first area A1, and the second opening 32 has a second area A2. The first area A1 can be larger than or equal to the second area A2. In some embodiments, since the first contact surface 401 and the second contact surface 453 correspond to the first opening 31 and the second opening 32 respectively, the area of the first contact surface 401 is substantially equal to the first area A1 of the first opening 31, and the area of the second contact surface 453 is substantially equal to the second area A2 of the second opening 32. In this embodiment, the first opening 31 and the second opening 32 have the same shape of circle, the first width L1 is substantially equal to the second width L2, and the first area A1 is substantially equal to the second area A2. When the plurality of first openings 31 and the plurality of second openings 32 are arranged in the array, the shortest distance between the edges of two adjacent first openings 31 is defined as a third distance D3. For example, for the first opening 31A and the adjacent first opening 31B in FIG. 3A, the shortest distance between their edges is drawn as the third distance D3.

Referring to the embodiment of FIG. 3B, in the top view, the plurality of second openings 32 is disposed at the central area between the two adjacent second sections 522a and 522b, and can be arranged in multiple columns, such as two or more columns, to further enhance the current passing through the central area, so as to improve the uniformity of light emission and reduce the operating voltage of the semiconductor device 100. In one embodiment, each column of the plurality of second openings 32 is parallel to the second section 522a and/or the second section 522b. The plurality of first openings 31 are located between the plurality of second openings 32 and the two second sections 522a and 522b. Similar to the embodiment of FIG. 3A, each of the first openings 31 has the first distance D1 thereof, and each of the second openings 32 has the second distance D2 thereof. As shown in FIG. 3B, the shortest distance between the first opening 31A and the closest second section 522a is drawn as an example of the first distance D1. For the second openings 32 in the left column, such as the second opening 32A, the shortest distance between the second opening 32A to the closest second section 522a is drawn as an example of the second distance D2. For the second openings 32 in the right column, such as the second opening 32C, the shortest distance between the second opening 32C to the closest second section 522b is drawn as another example of the second distance D2. In this embodiment, the first distance D1 is smaller than the second distance D2. The detailed descriptions of positions, relative relationships and material of other layers or structures as well as structural variations in this embodiment can be referred to the foregoing embodiments and are not repeatedly described herein.

Referring to the embodiment of FIG. 3C, in the top view, the plurality of second openings 32 is disposed in the central area between the two adjacent second sections 522a and 522b, and the second width L2 of each second opening 32 is smaller than the first width L1 of each first opening 31. In other words, the second area A2 of the second opening 32 is smaller than the first area A1 of the first opening 31. In this embodiment, each of the first openings 31 has the first distance D1 thereof, and each of the second openings 32 has the second distance D2 thereof. As shown in FIG. 3C, the first distance D1 of the first opening 31A and the second distance D2 of the second opening 32A are drawn for example. The detailed descriptions of positions, relative relationships and material of other layers or structures as well as structural variations in this embodiment can be referred to the foregoing embodiments and are not repeatedly described herein.

The arrangements of the plurality of first openings 31 and the plurality of second openings 32 shown in FIGS. 3A to 3C are not limited between the second section 522a and the second section 522b. Such arrangements of the plurality of first openings 31 and the plurality of second openings 32 can be applied between any two adjacent second sections, such as between the adjacent second sections 522b and 522c, and/or between the adjacent second sections 522c 522d, and/or between the adjacent second sections 522d and 522c.

Referring to FIG. 2, the semiconductor device 100 may optionally include a reflective structure 60 located between the base 10 and the first conductive structure 40, and a bonding structure 70 located between the base 10 and the reflective structure 60. The reflective structure 60 is located below and in contact with the first conductive structure 40. The bonding structure 70 is used to bond the base 10 to the reflective structure 60. The reflective structure 60 and the bonding structure 70 are conductive and can form electrical conduction between the base 10 and the first conductive structure 40.

The light emitted from the active structure 23 can penetrate the insulating structure 30 and/or the first conductive structure 40, and be reflected by the reflective structure 60 to emit outwards through the light-emitting surface. Thus, light emission orientation and the light extraction efficiency of the semiconductor device 100 can be improved. In one embodiment, the reflective structure 60 has a reflectivity of more than 80% for the light emitted from the active structure 23.

Although the second conductive structure 45 helps to improve current distribution, it may block the light reflected by the reflective structure 60 and reduce the light emission of the semiconductor device 100. In one embodiment, a sum of area of all the second contact surfaces 453 is smaller than a sum of area of all the first contact surfaces 401, so as to reduce light blocking effect of the second conductive structure 45. Furthermore, reducing the sum of area of the second contact surfaces 453 can further lower the light blocking effect of the second conductive structure 45. Specifically, since the second conductive structure 45 is located in the second opening 32 and the second conductive structure 45 and the second opening 32 have substantially the same shape, reducing the size of the second opening 32 (L2<L1) can correspondingly lower the area of the second contact surface 453, as shown in FIG. 3C. Thus, the light blocking effect of the second conductive structure 45 can be reduced. Alternatively, reducing the number of second openings 32 can also reduce the sum of area of the second contact surfaces 453 for lowering the light blocking effect of the second conductive structure 45. In one embodiment, a ratio of the sum of area of the second contact surfaces 453 to the sum of area of the first contact surfaces 401 can be between 0.1 and 0.6.

The semiconductor device 100 may also optionally include a protecting layer 80 disposed on the surface of the semiconductor stack 20 to improve reliability of the semiconductor device 100. Specifically, the protecting layer 80 covers the light-emitting surface of the semiconductor stack 20 and the first electrode structure 50 to avoid forming undesired electrical connection and prevent the semiconductor stack 20 from reacting with the external environment. The protecting layer 80 is transparent to the light emitted from the active structure 23. For example, the protecting layer 80 can have a transmittance of at least 80% for the light. In one embodiment, the protecting layer 80 includes a fourth opening 81 corresponding to the pad 51 for external wires to connect to the pad 51. In one embodiment, the fourth opening 81 may have a width smaller than that of the pad 51.

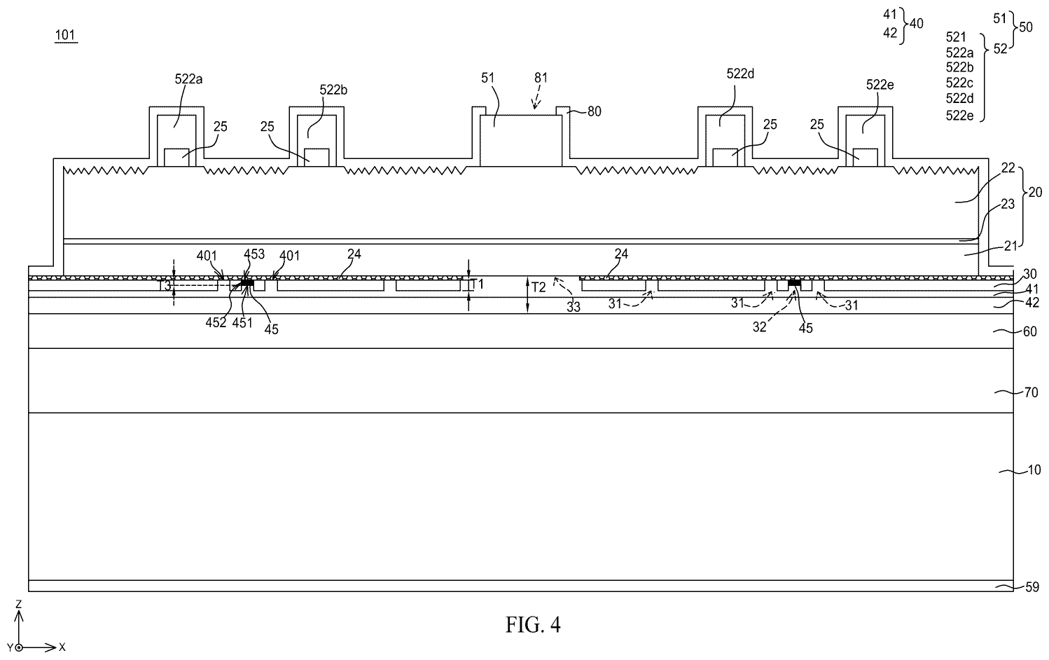

FIG. 4 is a schematic sectional view of a semiconductor device 101 according to another embodiment of the present disclosure. The semiconductor device 101 has a structure similar to that of the semiconductor device 100. In this embodiment, the first contact structure 24 is located between the first semiconductor structure 21 and the insulating structure 30, and the insulating structure 30 directly contacts the lower surface of the first contact structure 24. The second conductive structure 45 is located in the second opening 32 and contacts the first contact structure 24, and the first conductive structure 40 is located in the first opening 31 and contacts the first contact structure 24. In other words, the first contact surface 401 and the second contact surface 453 are substantially coplanar with the lower surface of the first contact structure 24.

In this embodiment, the insulating structure 30 only covers the side surface 452 of the second conductive structure 45 but does not cover the first surface 451 of the second conductive structure 45, so that the insulating structure 30 does not form the aforementioned stepped structure. In this embodiment, the upper end and the lower end of the second opening 32 have the same width, that is, the second opening 32 has the same area at the upper end and the lower end.

In this embodiment, the first conductive structure 40 includes a first conductive layer 41 and a second conductive layer 42. The first conductive layer 41 and the second conductive layer 42 may include the same or different materials. The first conductive layer 41 is disposed between the insulating structure 30 and the reflective structure 60, and is located in the first opening 31 and the second opening 32 to contact the first contact structure 24 (or the first semiconductor structure 21) and/or the second conductive structure 45. The second conductive layer 42 is disposed between the first conductive layer 41 and the reflective structure 60 to enhance the current spreading effect and reliability. In the vertical direction, the first conductive layer 41 may have a thickness larger than or equal to the first thickness T1 of the insulating structure 30. In this embodiment, the thickness of the first conductive layer 41 is larger than the first thickness T1. The detailed descriptions of positions, relative relationships and material of other layers or structures as well as structural variations in this embodiment can be referred to the foregoing embodiments and are not repeatedly described herein.

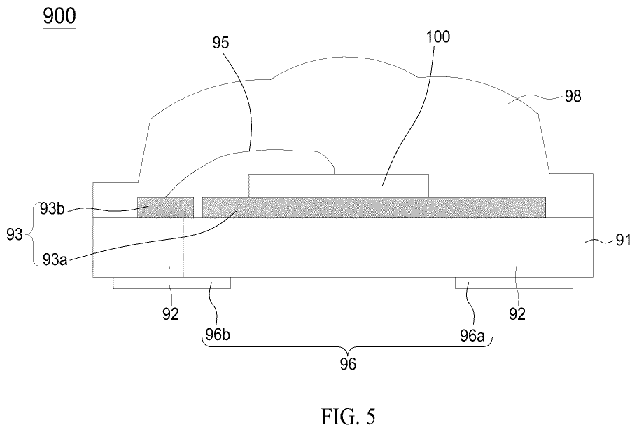

FIG. 5 shows a schematic sectional view of a package structure 900 in accordance with an embodiment of the present disclosure. As shown in FIG. 5, the package structure 900 includes a semiconductor device 100, a package substrate 91, a carrier 93, a bonding wire 95, an electric connecting portion 96 and an encapsulating structure 98. The package substrate 91 may include a ceramic or glass. The package substrate 91 has a plurality of through holes 92. Each through hole 92 may be filled with a conductive material such as metal for electrical conduction and/or heat dissipation. The carrier 93 may be located on a surface of one side of the package substrate 91 and may include a conductive material such as metal. The electric connecting portion 96 is on a surface on another side of the package substrate 91. In the embodiment, the electric connecting portion 96 includes a first contact pad 96a and a second contact pad 96b, and the first contact pad 96a and the second contact pad 96b can be electrically connected to the carrier 93 through the through holes 92. In an embodiment, the electric connecting portion 96 may further include a thermal pad (not shown), for example, between the first contact pad 96a and the second contact pad 96b.

The semiconductor device 100 is located on the carrier 93 and may be the semiconductor device as described in any embodiment of the present disclosure (such as the semiconductor devices 100, 101 and variations thereof). In the embodiment, the carrier 93 includes a first portion 93a and a second portion 93b, and the semiconductor device 100 is electrically connected to the second portion 93b of the carrier 93 by the bonding wire 95. The material of the bonding wire 95 may include metal, such as gold (Au), silver (Ag), copper (Cu), or aluminum (Al), or may include alloy containing one or more of the above metals. The encapsulating structure 98 covers the semiconductor device 100 and protects the semiconductor device 100. Specifically, the encapsulating structure 98 may include a resin material, such as an epoxy resin, or a silicone resin. The encapsulating structure 98 may further include a plurality of wavelength conversion particles (not shown) to convert a first light emitted by the semiconductor device 100 into a second light. The wavelength of the second light is greater than the wavelength of the first light.

The semiconductor device or the package structure of the present disclosure can be applied to products in various fields, such as illumination, medical care, display, communication, sensing, or power supply system, for example, can be used in a light fixture, monitor, mobile phone, tablet, an automotive instrument panel, a television, computer, wearable device (such as watch, bracelet or necklace), traffic sign, outdoor display device, or medical device.

The base 10 can include conductive materials, such as gallium arsenide (GaAs), indium phosphide (InP), silicon carbide (SiC), gallium phosphide (GaP), zinc oxide (ZnO), gallium nitride (GaN), aluminum nitride (AlN), germanium (Ge) or silicon (Si).

The first semiconductor structure 21, the second semiconductor structure 22, the active structure 23, the first contact structure 24 and/or the second contact structure 25 can include III-IV compound semiconductor, such as GaAs, InGaAs, AlGaAs, AlInGaAs, GaP, InGaP, AlInP, AlGaInP, GaN, InGaN, AlGaN, AlInGaN, AlAsSb, InGaAsP, InGaAsN, AlGaAsP.

The insulating structure 30 can include insulating materials, such as silicon nitride (SiNₓ), aluminum oxide (AlOₓ), silicon oxide (SiOₓ), magnesium fluoride (MgFₓ), titanium oxide (TiOₓ), niobium pentoxide (Nb₂O₅) or combinations thereof. In some embodiment, the insulating structure 30 may include a distributed bragg reflector (DBR) structure. The DBR structure may include a plurality of first dielectric layers and a plurality of second dielectric layers that are alternately stacked with each other, and the first dielectric layers and the second dielectric layers have different refractive indices. For example, the DBR structure may be a combination of TiO_{2/}Nb₂O₅ or a combination of SiO₂/Nb₂O₅.

The first conductive structure 40 can include a metal oxide. The metal oxide may include indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium zinc oxide (GZO), zinc oxide (ZnO), indium cerium oxide (ICO), indium tungsten oxide (IWO), indium titanium oxide (ITiO), indium zinc oxide (IZO), indium gallium oxide (IGO) or gallium aluminum zinc oxide (GAZO).

The second conductive structure 45 can include a metal or an alloy, such as gold (Au), BeAu or TiAu.

The first electrode structure 50 and/or the second electrode structure 59 can include a metal oxide, a metal or an alloy, and the first electrode structure 50 and the second electrode structure 59 may have the same or different materials. The metal oxide may include indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium zinc oxide (GZO), indium tungsten oxide (IWO), zinc oxide (ZnO) or indium zinc oxide (IZO). The metal may include germanium (Ge), beryllium (Be), zinc (Zn), titanium (Ti), aluminum (Al), nickel (Ni), gold (Au), platinum (Pt), tin (Sn) or copper (Cu). The alloy may include at least two of the above metals, such as such as GeAuNi, BeAu, GeAu or ZnAu.

The reflective structure 60 can include a metal or an alloy. The metal may include copper (Cu), aluminum (Al), tin (Sn), gold (Au) or silver (Ag). The alloy may include at least two of the above metals.

The bonding structure 70 can include a metal oxide, a metal, or an alloy. The metal oxide may include indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium zinc oxide (GZO), zinc oxide (ZnO), gallium phosphide (GaP), indium cerium oxide (ICO), indium tungsten oxide (IWO), indium titanium oxide (ITiO), indium zinc oxide (IZO), indium gallium oxide (IGO), gallium aluminum zinc oxide (GAZO) or a combination of the above metal oxides. The metal may include aluminum (Al), nickel (Ni), gold (Au), silver (Ag), titanium (Ti), tungsten (W), platinum (Pt), tin (Sn), indium (In) or copper (Cu). The alloy may include at least two of the above metals.

The protecting layer 80 can include an insulating material, such as tantalum oxide (TaOₓ), aluminum oxide (Al₂O₃), silicon oxide (SiOₓ), titanium oxide (TiOₓ), silicon nitride (SiNₓ), silicon oxynitride (SiOₓN_{y}), niobium pentoxide (Nb₂O₅) or spin-on glass (SOG).

The semiconductor device and/or the package structure of the present disclosure can be applied to products in various fields, such as illumination, medical care, display, communication, sensing, or power supply system, for example, can be used in a light fixture, monitor, mobile phone, tablet, an automotive instrument panel, a television, computer, wearable device (such as watch, bracelet or necklace), traffic sign, outdoor display device, or medical device.

The embodiments of the present disclosure will be described in detail below with reference to the drawings. In the descriptions of the specification, specific details are provided for a full understanding of the present disclosure. The same or similar components in the drawings will be denoted by the same or similar symbols. It is noted that the drawings are for illustrative purposes only and do not represent the actual dimensions or quantities of the components. Some of the details may not be fully sketched for the conciseness of the drawings.

What is claimed is:

1. A semiconductor device, comprising:
a semiconductor stack comprising a first semiconductor structure, a second semiconductor structure and an active structure located between the first semiconductor structure and the second semiconductor structure;
an insulating structure disposed below the first semiconductor structure and comprising a first opening and a second opening;
a metal oxide structure disposed below the insulating structure and located in the first opening, wherein the metal oxide structure contacts the semiconductor stack to form a first contact surface therebetween; and
a metal structure located in the second opening and contacting the semiconductor stack to form a second contact surface therebetween, wherein the second contact surface is separated from the first contact surface.

2. The semiconductor device according to claim 1, further comprising a first electrode structure disposed on the second semiconductor structure, wherein the second contact surface does not overlap with the first electrode structure in a vertical direction.

3. The semiconductor device according to claim 2, wherein the first electrode structure comprises a pad, and the first contact surface overlaps the pad in the vertical direction.

4. The semiconductor device according to claim 3, wherein the insulating structure does not overlap with the pad in the vertical direction.

5. The semiconductor device according to claim 2, wherein the first electrode structure comprises a first section and a second section which are parallel to each other, and the first opening and the second opening are located between the first section and the second section and do not overlap with the first section and the second section in the vertical direction.

6. The semiconductor device according to claim 5, wherein in a top view, the first opening is located between the second opening and the first section or between the second opening and the second section.

7. The semiconductor device according to claim 6, wherein a distance between the second opening and the first section is in a range of 20 μm to 100 μm.

8. The semiconductor device according to claim 2, wherein the metal oxide structure extends in into the second opening to contact the metal structure.

9. The semiconductor device according to claim 2, wherein the metal structure comprises a first surface facing the metal oxide structure, and the first surface is partially covered by the insulating structure.

10. The semiconductor device according to claim 2, wherein the metal oxide structure comprises a first conductive layer and a second conductive layer.

11. The semiconductor device according to claim 1, further comprising a reflective structure located below the insulating structure and connecting the metal oxide structure.

12. The semiconductor device according to claim 11, further comprising a base located below the reflective structure and a bonding structure located between the base and the reflective structure.

13. The semiconductor device according to claim 1, wherein the first contact surface has an area larger than that of the second contact surface.

14. The semiconductor device according to claim 1, wherein the first opening has a first area, and the second opening has a second area smaller than the first area.

15. The semiconductor device according to claim 1, wherein the first contact surface and the second contact surface are substantially coplanar.

16. The semiconductor device according to claim 1, wherein the insulating structure has a first thickness and the metal structure has a second thickness smaller than the first thickness.

17. The semiconductor device according to claim 1, wherein the metal structure has a thickness in a range of 100 nm to 500 nm.

18. The semiconductor device according to claim 1, wherein the semiconductor stack comprises a first contact structure disposed between the first semiconductor structure and the insulating structure.

19. The semiconductor device according to claim 18, wherein the semiconductor stack comprises a plurality of first contact structures located in the first opening and the second opening.

20. A package structure comprising:
a package substrate;
the semiconductor device of claim 1 on the package substrate; and
an encapsulating structure covering the semiconductor device.
